(19) United States
(12) Patent Application Publication
(10) Pub. No.: US 2016/0100481 A1
(43) Pub. Date: Apr. 7, 2016

(54) ANISOTROPIC CONDUCTIVE FILM, METHOD OF MANUFACTURING THE SAME, AND PRINTED CIRCUIT BOARD USING THE SAME

(71) Applicant: SAMSUNG ELECTRO-MECHANICS CO., LTD., Suwon-Si (KR)

(72) Inventor: Young Soon KIM, Suwon-Si (KR)

(21) Appl. No.: 14/755,947

(22) Filed: Jun. 30, 2015

(30) Foreign Application Priority Data
Oct. 1, 2014 (KR) 10-2014-0132624

(51) Int. Cl. H05K 1/03; H01B 1/20; H05K 1/02; B29C 39/00

(52) U.S. Cl. CPC H05K 1/0353; B29C 39/003; H01B 1/20; H05K 1/0298; B29K 2995/0005; B29L 2007/008

(57) ABSTRACT

There are provided an anisotropic conductive film, a method of manufacturing the same, and a printed circuit board using the same. More specifically, the anisotropic conductive film according to an exemplary embodiment of the present disclosure includes an insulating mattress containing a non-conductive polymer, and a plurality of conductive cylinders formed in a direction from an upper surface to a lower surface of the insulating mattress, containing a conductive polymer. Further, the printed circuit board using the anisotropic conductive film of the present disclosure may prevent open or short between upper circuit patterns and lower circuit patterns, and allow a fine pitch between the circuit patterns, due to the structure of the anisotropic conductive film formed between the substrates.

### CROSS-REFERENCE TO RELATED APPLICATION

This application claims the benefit of Korean Patent Application No. 10-2014-0132624, filed on Oct. 1, 2014, entitled “Anisotropic Conductive Film, Method of Manufacturing the Same, and Printed Circuit Board using the Same” which is hereby incorporated by reference in its entirety into this application.

### BACKGROUND

The present disclosure relates to an anisotropic conductive film, a method of manufacturing the same, and a printed circuit board using the same.

An electronic packaging technology is a broad and various system manufacturing technology including all steps ranging from a semiconductor device to a final product, which is important in determining performance, size, price, reliability, and the like of a final electronic product.

For example, in the packaging of a liquid crystal display (LCD), a conductive adhesive is used for mechanical and electrical connection between a printed circuit board and a transparent electrode, and among them, particularly an anisotropic conductive film (ACF) is used.

As the conductive adhesive, there are largely some types of products such as an anisotropic conductive film, an isotropic conductive adhesive (ICA), and the like, and basically, the conductive adhesive is in the form in which electrically conductive particles such as nickel (Ni) or Ni/polymer, silver (Ag) and the like are dispersed in a thermosetting or thermoplastic insulating resin.

The anisotropic conductive film is consisting of electrically conductive particles and an insulating resin, wherein as the electrically conductive particles having an electrical role, initially powder or fibrous carbon-based materials were used, and then a solder ball was used, and subsequently nickel particles or a polymer ball having nickel coated on the surface thereof is now used.

Further, in order to secure space within a limited area, and implement a high difficulty product being consistently developed, and a fine pitch between circuit patterns, an anisotropic conductive film using conductive particles may, if the amount of the conductive particles is increased, generate short, and if the amount of the conductive particles is decreased, generate an open phenomenon.

### RELATED ART DOCUMENT

### Patent Document

(Patent Document 1) Korean Patent Laid-Open Publication No. 2014-0078557

### SUMMARY

An aspect of the present disclosure may provide an anisotropic conductive film in which a non-conductive polymer and a conductive polymer form a block copolymer.

Another aspect of the present disclosure may provide a method of manufacturing the anisotropic conductive film.

Still another aspect of the present disclosure may provide a printed circuit board using the anisotropic conductive film.

According to an aspect of the present disclosure, an anisotropic conductive film may include an insulating mattress containing a non-conductive polymer, and a plurality of conductive cylinders formed in a direction from an upper surface to a lower surface of the insulating mattress, containing a conductive polymer.

The insulating mattress and the conductive cylinder may be formed of a block copolymer.

The insulating mattress may contain one or more selected from the group consisting of an epoxy resin and an acrylate resin.

The conductive cylinder may contain one or more selected from the group consisting of polyacetylene, poly(p-phenylene), polypyrrole and polyaniline

According to another aspect of the present disclosure, a method of manufacturing an anisotropic conductive film may include:
stirring a composition containing a non-conductive polymer and a conductive polymer;
applying the stirred composition on a release film and semi-curing the stirred composition; and
removing the release film.

According to still another aspect of the present disclosure, a printed circuit board may include:
a first substrate on which a first circuit pattern is formed;
an anisotropic conductive film formed on the first substrate on which the first circuit pattern is formed; and
a second substrate on which a second circuit pattern is formed, formed on the anisotropic conductive film.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of an anisotropic conductive film according to an exemplary embodiment of the present disclosure;

FIG. 2 is a cross-sectional view taken along the cut line A-A′ of an anisotropic conductive film according to an exemplary embodiment of the present disclosure;

FIG. 3 is a perspective view schematically illustrating an anisotropic conductive film according to an exemplary embodiment of the present disclosure stacked between substrates on which circuit patterns are formed; and

FIG. 4 is a perspective view schematically illustrating a printed circuit board to which an anisotropic conductive film according to an exemplary embodiment of the present disclosure is applied.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

Anisotropic Conductive Film

An anisotropic conductive film according to an exemplary embodiment of the present disclosure may include an insulating mattress containing a non-conductive polymer, and a plurality of conductive cylinders formed in a direction from an upper surface to a lower surface of the insulating mattress, containing a conductive polymer.

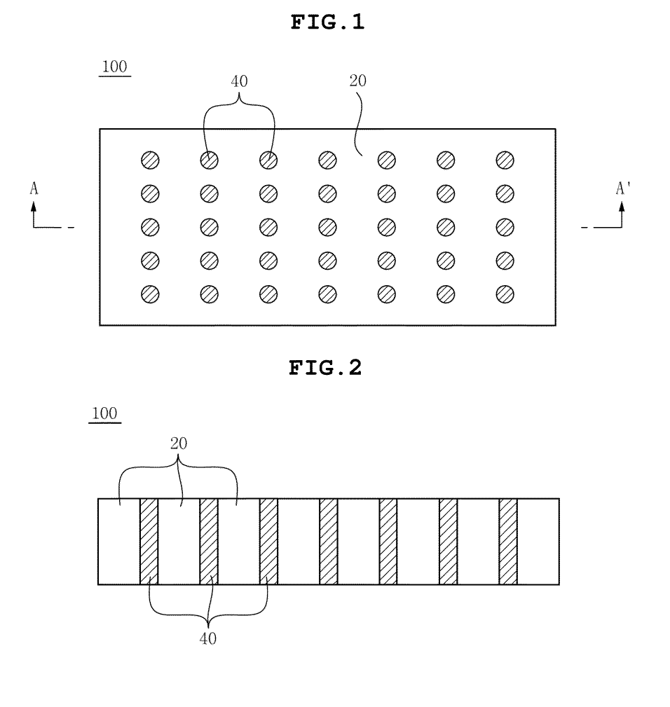

FIG. 1 is a plan view of an anisotropic conductive film according to an exemplary embodiment of the present disclosure, and FIG. 2 is a cross-sectional view taken along the cut line A-A′ of the anisotropic conductive film of FIG. 1.

Referring to FIGS. 1 and 2, the anisotropic conductive film 100 according to an exemplary embodiment of the present disclosure has a structure in which a plurality of conductive cylinders 40 are formed in the inside of an insulating mattress 20, wherein the plurality of conductive cylinders 40 may be formed in a direction from an upper surface to a lower surface of the insulating mattress 20, that is, a thickness direction of the insulating mattress 20.

Eventually, in the anisotropic conductive film 100 including the plurality of conductive cylinders 40, since the conductive cylinders 40 are formed along a straight line in a thickness direction, as shown in FIG. 2, they may be a passage for electrical connection in a direction from an upper surface to a lower surface of the insulating mattress 20.

The anisotropic conductive film 100 according to an exemplary embodiment of the present disclosure including the insulating mattress 20 and the plurality of conductive cylinders may be formed of a block copolymer of a non-conductive polymer and a conductive polymer.

Herein, the block copolymer refers to a polymer in which two or more polymers having different properties are connected to each other by a covalent bond, and it is possible to synthesize a polymer material having physical properties of each polymer. Since in the block copolymer, two or more polymers having different properties are connected to each other by a covalent bond, the block polymer undergoes phase separation at constant temperature and pressure. The size and shape of the domain formed at this time vary depending on the length and relative amount of each polymer segment, and by adjusting them under an appropriate condition, the anisotropic conductive film according to an exemplary embodiment of the present disclosure, may be formed. The block copolymer is a representative material having a self-assembling property, in which a polymer having a covalent bond between atoms may spontaneously form a certain nanostructure by mutual attraction between molecules.

The anisotropic conductive film 100 according to an exemplary embodiment of the present disclosure includes the plurality of conductive cylinders 40 in a cylindrical shape, formed in the inside of the insulating mattress 20, in a direction from upper surface to the lower surface. More specifically, the anisotropic conductive film 100 having the plurality of conductive cylinders 40 formed in the inside of the insulating mattress 20, is in the form in which the insulating mattress 20 and conductive cylinders 40 are alternately formed in a thickness direction. This may lead each substrate on which a pad for electrical connection is formed to be stacked on the upper and lower surfaces of the anisotropic conductive film 100, and the anisotropic conductive film may secure adhesive strength between substrates, and at the same time, make electrical connection through the plurality of conductive cylinders 40 formed in a thickness direction.

Moreover, the anisotropic conductive film 100 according to an exemplary embodiment of the present disclosure has an advantage that the substrates capable of being stacked on the upper and lower surfaces do not generate failure such as open or short, due to the structure of the anisotropic conductive film, even in the case where the pitch of the circuit patterns may be finely formed. Therefore, the substrates on which fine circuit patterns are formed, may be electrically connected to each other by applying the anisotropic conductive film 100.

The insulating mattress 20 may contain a non-conductive polymer, specifically one or more selected from the group consisting of an epoxy resin and an acrylate resin.

More specifically, the epoxy resin may increase a handling property of the resin composition as an adhesive film, after drying, and it will be fine to contain one or more epoxy functional groups in the molecule. The epoxy resin may be one or more selected from the group consisting of a naphthalene-based epoxy resin, a bisphenol

A-type epoxy resin, a phenol novolac resin, a cresol novolac epoxy resin, a rubber-modified epoxy resin, a phosphorous-based epoxy resin, and bisphenol F-type epoxy resin, but the present disclosure is not specially limited thereto.

The acrylate resin may be one or more selected from the group consisting of an alkylglycidylether (meth)acrylate resin, a phenylglycidylether (meth)acrylate resin, a (meth)acrylate resin and a polyfunctional (meth) acrylate resin, but the present disclosure is not specially limited thereto.

The conductive cylinder 40 may contain a conductive polymer, specifically one or more selected from the group consisting of polyacetylene, poly(p-phenylene), polypyrrole and polyaniline.

The anisotropic conductive film 100 may further include a curing agent for curing the polymer material. Specifically, the curing agent may be one or more selected from the group consisting of an amine-based curing agent, an acid hydride-based curing agent, a polyamine curing agent, a polysulfide curing agent, a phenol novolac-type curing agent, a bisphenol A-type curing agent, a dicyandiamide curing agent, and a tetraphenylethane curing agent, alone or in a mixture of two or more thereof, but the present disclosure is not specially limited thereto.

Further, the anisotropic conductive film 100 may selectively include a curing accelerator for efficient curing. The curing accelerator may include a metal-based curing accelerator, an imidazole-based curing accelerator, and an amine-based curing accelerator, and these may be used alone or in a mixture of two or more. However, the present disclosure is not specially limited thereto.

The metal-based curing accelerator may include, though not specially limited to, an organic metal complex or an organic metal salt of metals such as cobalt, copper, zinc, iron, nickel, manganese, tin, and the like. The specific examples of the organic metal complex may include an organic cobalt complex such as cobalt (II) acetylacetonate and cobalt (III) acetylacetonate, a free copper complex such as copper (II) acetylacetonate, an organic zinc complex such as zinc (II) acetylacetonate, an organic iron complex such as iron (III) acetylacetonate, an organic nickel complex such as nickel (II) acetylacetonate, an organic manganese complex such as manganese (II) acetylacetonate, and the like. The organic metal salt may include zinc octylate, tin octylate, zinc naphthenate, cobalt naphthenate, tin stearate, zinc stearate and the like.

The metal-based curing accelerator is, in terms of curing, and solubility in a solution, preferably cobalt (II) acetylacetonate, cobalt (III) acetylacetonate, zinc (II) acetylacetonate, zinc naphthenate, iron (III) acetylacetonate, and the like, and particularly cobalt (II) acetylacetonate, and zinc naphthenate is preferred. The metal-based curing accelerator may be used alone or in a mixture of two or more.

The imidazole-based curing accelerator may include, though not specially limited to, an imidazole compound such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazoliumtrimellitate, 1-cyanoethyl-2-phenyllimidazoliumtrimellitate, 2,4-diamino-6-[2′ -methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, 2-phenyl-4-methyl-5hydroxymethylimidazole,2,3-dihydroxy-1H-pyrrolo[1,2-a]benzimi dazole, 1-dodecyl-2-methyl-3-benzylimidazolium chloride, 2-methylimidazoline, 2-phenylimidazoline, and the like, and additives of the imidazole compound and the epoxy resin. The imidazole curing accelerator may be used alone or in a mixture of two or more.

The amine-based curing accelerator may include, though not specially limited to, trialkyl amine such as triethylamine and tributylamine, an amine compound such as 4-dimethylaminopyrridine, benzyldimethylamine, 2,4,6-tris(dimethylaminomethyl) phenol, 1,8-diazabicyclo (5,4,0)-undecene, and the like. The amine-based curing accelerator may be used alone or in a mixture of two or more.

In addition, the anisotropic conductive film 100 may further include a solvent for organic combination between the non-conductive polymer and the conductive polymer. Specifically, the solvent may be one or more selected from the group consisting of poly-alcohol, dimethyl sulfoxide (DMSO), N,N-dimethylformamide, ethylene glycol (EG), polyethyleneglycol, meso-erythritol, aniline, acetone, methylethylketone, isopropylalcohol, butylalcohol, ethylalcohol, methylalcohol, dimethylacetamide, hexane, toluene, chloroform, cyclohexanone, distilled water, pyridine, methylnaphthalene, octamesylamine, tetrahydrofurane, dichlorobenzene, dimethylbenzene, trimethylbenzene, nitromethane, acrylonitrile, pure water (H₂O), which may be used alone or in a mixture of two or more, but the present disclosure is not specially limited thereto.

Method of Manufacturing Anisotropic Conductive Film

A method of manufacturing an anisotropic conductive film 100 according to an exemplary embodiment of the present disclosure may include:
stirring a composition containing a non-conductive polymer and a conductive polymer;
applying the stirred composition on a release film and semi-curing the stirred composition; and
removing the release film.

The step of stifling the composition containing the non-conductive polymer and the conductive polymer may be carried out using beads in a ball mill, but the present disclosure is not specially limited thereto.

The non-conductive polymer and the conductive polymer contained in the composition may form a block copolymer by a covalent bond, and the shape of the anisotropic conductive film 100 according to an exemplary embodiment of the present disclosure may be obtained therefrom.

The non-conductive polymer may contain one or more selected from the group consisting of an epoxy resin and an acrylate resin, and the conductive resin may contain one or more selected from the group consisting of polyacetylene, poly(p-phenylene), polypyrrole and polyaniline, but the present disclosure is not specially limited thereto. More detailed description is as described above, and thus, will be omitted herein.

The step of applying the composition on a release film, and semi-curing it may be carried out by a coating method selected from the group consisting of a comma coating, a roll coating, a spin coating, a slot die coating, a spray coating, and an inkjet coating methods, and a comma coating method is generally applied, but the present disclosure is not specially limited thereto.

The release film which is a sticky polymer, may be one or more selected from the group consisting of fluorine-based, silicon-based, polyethyleneterephthalate, polymethylpentene, and the mixture thereof, but the present disclosure is not specially limited thereto.

Printed Circuit Board

A printed circuit board 500 according to an exemplary embodiment of the present disclosure includes:
a first substrate 200 on which a first circuit pattern 201 is formed;
an anisotropic conductive film 100 formed on the first substrate 200 on which the first circuit pattern 201 is formed; and
a second substrate 300 on which a second circuit pattern 301 is formed, formed on the anisotropic conductive film.

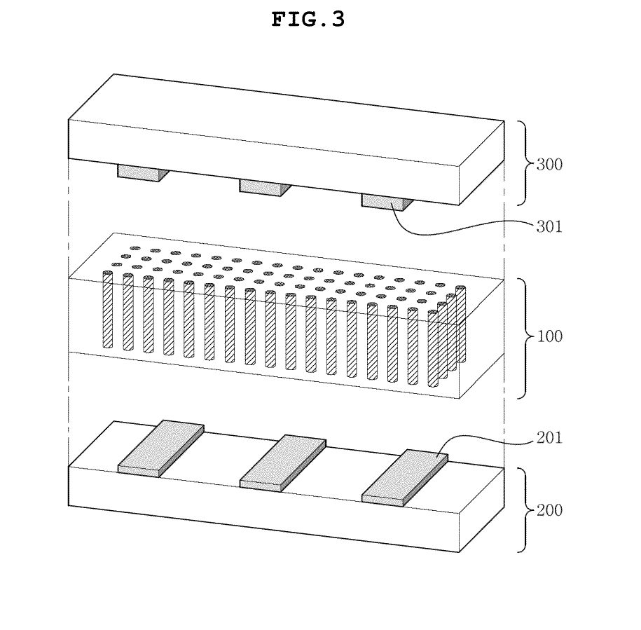

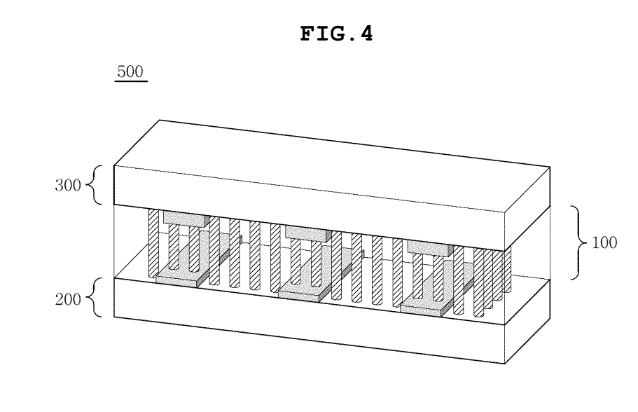

FIG. 3 is a perspective view schematically illustrating an anisotropic conductive film 100 according to an exemplary embodiment of the present disclosure stacked between substrates on which circuit patterns are formed, and FIG. 4 is a perspective view schematically illustrating a printed circuit board 500 to which an anisotropic conductive film according to an exemplary embodiment of the present disclosure is applied.

Referring to FIGS. 3 and 4, the printed circuit board 500 according to an exemplary embodiment of the present disclosure may be formed by bonding the first substrate 200 on which the first circuit pattern 201 is formed, and the second substrate 300 on which the second circuit pattern 301 is formed, through the anisotropic conductive film 100 according to an exemplary embodiment of the present disclosure between each substrate.

Herein, the first circuit pattern 201 and the second circuit pattern 301 may make electrical connection vertically, through the plurality of conductive cylinders 40 present in the anisotropic conductive film 100. Due to the structure of the anisotropic conductive film 100 including the plurality of conductive cylinders 40, electrical open or short failure between the substrates including the circuit patterns on upper/lower surfaces thereof may be inhibited. Further, though the circuit patterns are formed at a fine pitch on each substrate, the anisotropic conductive film according to an exemplary embodiment of the present disclosure may be applied thereto.

Therefore, the printed circuit board 500 including the anisotropic conductive film 100 according to an exemplary embodiment of the present disclosure may be applied to circuit patterns formed at a fine pitch, and this leads to inhibition of electrical problems such as open or short.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. An anisotropic conductive film comprising:
an insulating mattress containing a non-conductive polymer; and
a plurality of conductive cylinders formed in a direction from an upper surface to a lower surface of the insulating mattress, containing a conductive polymer.

2. The anisotropic conductive film of claim 1, wherein the insulating mattress and the conductive cylinder are formed of a block copolymer.

3. The anisotropic conductive film of claim 1, wherein the insulating mattress contains one or more selected from the group consisting of an epoxy resin and an acrylate resin.

4. The anisotropic conductive film of claim 1, wherein the conductive cylinder contains one or more selected from the group consisting of polyacetylene, poly(p-phenylene), polypyrrole and polyaniline.

5. A method of manufacturing an anisotropic conductive film comprising:
stirring a composition containing a non-conductive polymer and a conductive polymer;
applying the stirred composition on a release film and semi-curing the stirred composition; and
removing the release film.

6. The method of claim 5, wherein the stirring of the composition is carried out using beads in a ball mill.

7. The method of claim 5, wherein the non-conductive polymer and the conductive polymer form a block copolymer by a covalent bond.

8. The method of claim 5, wherein the non-conductive polymer contains one or more selected from the group consisting of an epoxy resin and an acrylate resin.

9. The method of claim 5, wherein the conductive polymer contains one or more selected from the group consisting of polyacetylene, poly(p-phenylene), polypyrrole and polyaniline.

10. The method of claim 5, wherein the applying and semi-curing of the composition on the release film are carried out by a coating method selected from the group consisting of a comma coating, a roll coating, a spin coating, a slot die coating, a spray coating and an inkjet coating methods.

11. A printed circuit board comprising:
a first substrate on which a first circuit pattern is formed;
an anisotropic conductive film formed on the first substrate on which the first circuit pattern is formed; and
a second substrate on which a second circuit pattern is formed, formed on the anisotropic conductive film.
